(19) United States
(12) Patent Application Publication
(10) Pub. No.: US 2026/0303059 A1
(43) Pub. Date: Oct. 1, 2026

(54) ACOUSTIC WAVE DEVICE, ACOUSTIC WAVE FILTER, AND MULTIPLEXER

(71) Applicant: Murata Manufacturing Co., Ltd., Nagaokakyo-shi (JP)

(72) Inventor: Yohei KONAKA, Nagaokakyo-shi (JP)

(21) Appl. No.: 19/629,436

(22) Filed: Mar. 26, 2026

(30) Foreign Application Priority Data
Mar. 27, 2025 (JP) 2025-053524

(51) Int. Cl. H03H 9/145; H03H 9/02; H03H 9/25; H03H 9/64

(52) U.S. Cl. CPC H03H 9/14582; H03H 9/02559; H03H 9/02637; H03H 9/02866; H03H 9/25; H03H 9/6483; H03H 9/6496

(57) ABSTRACT

An acoustic wave device includes an IDT electrode and a reflector electrode. The IDT electrode includes comb electrode fingers. The reflector electrode includes reflector electrode fingers. Comb electrode fingers in a direction from a comb electrode finger closest to the reflector electrode toward a center of the IDT electrode are defined as nth end-side electrode fingers. A center-to-center distance between the electrode fingers adjacent to each other in the first direction is defined as a pitch. A pitch between an nth end-side electrode finger and an (n+1)th end-side electrode finger is defined as an nth end-side pitch. An mth end-side pitch is smaller than an average pitch. In the IDT electrode, when a region from the first end-side electrode finger to the mth end-side electrode finger is defined as an end region, the IDT electrode includes a thinned electrode in the end region.

### CROSS REFERENCE TO RELATED APPLICATIONS

This application claims the benefit of priority to Japanese Patent Application No. 2025-053524 filed on Mar. 27, 2025. The entire contents of this application are hereby incorporated herein by reference.

### BACKGROUND OF THE INVENTION

### 1. Field of the Invention

The present invention relates to acoustic wave devices, acoustic wave filters, and multiplexers.

### 2. Description of the Related Art

International Publication No. 2023/282328 discloses an acoustic wave element that, for reducing ripples close to a resonant frequency, defines the relationship between a pitch of an nth end-side electrode finger (nth end-side pitch) positioned at nth counted from an end portion of an interdigital transducer (IDT) electrode and a gap between the IDT electrode and the reflector (IDT-reflector gap).

When configuring a filter using the acoustic wave element described in International Publication No. 2023/282328, to optimize the steepness of a pass bandwidth and a pass band end portion, it is required to adjust a resonant bandwidth (a difference frequency of an anti-resonant frequency and a resonant frequency) of the acoustic wave element.

### SUMMARY OF THE INVENTION

Example embodiments of the present invention provide acoustic wave devices, acoustic wave filters, and multiplexers that each reduce ripples close to a resonant frequency and enable adjustment of a resonance bandwidth.

According to an example embodiment of the present invention, an acoustic wave device includes a piezoelectric substrate, an interdigital transducer electrode on the piezoelectric substrate, and a reflector electrode on the piezoelectric substrate so as to be adjacent to the interdigital transducer electrode in a first direction. The interdigital transducer electrode includes a plurality of comb electrode fingers extending in a second direction intersecting the first direction. The reflector electrode includes a plurality of reflector electrode fingers extending in the second direction. Among the plurality of comb electrode fingers, a comb electrode finger closest to the reflector electrode is defined as a first end-side electrode finger, and the comb electrode fingers arranged in a direction from the first end-side electrode finger toward a center of the interdigital transducer electrode are sequentially defined as nth end-side electrode fingers, where n is a natural number. Among electrode fingers of the plurality of comb electrode fingers and the plurality of reflector electrode fingers, a center-to-center distance in the first direction between the electrode fingers adjacent to each other in the first direction is defined as a pitch, and a pitch between an nth end-side electrode finger and an (n+1)th end-side electrode finger is defined as an nth end-side pitch. Among pitches arranged from the first end-side electrode finger to a comb electrode finger positioned in the center of the interdigital transducer electrode, an mth end-side pitch is smaller than an average of pitches of the plurality of comb electrode fingers, except for the mth end-side pitch. In a region where the interdigital transducer electrode is located, when a region from the first end-side electrode finger to the mth end-side electrode finger is defined as an end region, the interdigital transducer electrode includes a thinned electrode in the end region.

According to another example embodiment of the present invention, an acoustic wave filter includes an acoustic wave device according to an example embodiment of the present invention.

According to another example embodiment of the present invention, a multiplexer includes a common terminal, an acoustic wave filter according to an example embodiment of the present invention connected to the common terminal, and a first filter connected to the common terminal.

According to example embodiments of the present invention, acoustic wave devices, acoustic wave filters, and multiplexers each reduce ripples close to a resonant frequency and enable adjustment of a resonance bandwidth are provided.

The above and other elements, features, steps, characteristics and advantages of the present invention will become more apparent from the following detailed description of the example embodiments with reference to the attached drawings.

### BRIEF DESCRIPTION OF THE DRAWINGS

FIGS. 1A and 1B are plan views of an acoustic wave device according to an example embodiment of the present invention.

FIG. 2A is a sectional view of an acoustic wave device according to an example embodiment of the present invention.

FIG. 2B is a sectional view of an acoustic wave device according to a modification of an example embodiment of the present invention.

FIGS. 3A and 3B include graphs illustrating the impedance characteristics and the reflection characteristics of acoustic wave devices according to comparative examples 1 and 2.

FIGS. 4A to 4C include graphs illustrating the reflection characteristics of acoustic wave devices according to comparative examples 2 and 3 and example 1.

FIGS. 5A to 5C include graphs illustrating the reflection characteristics of acoustic wave devices according to comparative examples 4 and 5 and example 2.

FIGS. 6A and 6B include graphs illustrating the reflection characteristics of acoustic wave devices according to examples 3 and 4.

FIG. 7A includes plan views schematically illustrating configurations of the electrodes of acoustic wave device devices according to examples 5 to 9.

FIG. 7B illustrates relationships between a narrow pitch position and return loss of the acoustic wave devices according to examples 5 to 9.

FIG. 8 illustrates relationships between the narrow pitch position and the return loss of acoustic wave devices according to comparative example 6 and examples 10 to 14.

FIGS. 9A and 9B include graphs illustrating the impedance characteristics and the reflection characteristics of acoustic wave devices according to comparative example 7 and example 15.

FIG. 10A includes plan views schematically illustrating configurations of electrodes of acoustic wave devices according to examples 16 to 20.

FIG. 10B illustrates relationships between a narrow pitch position and return loss of the acoustic wave devices according to examples 16 to 20.

FIG. 11 is a circuit configuration diagram of a multiplexer according to an example embodiment of the present invention.

### DETAILED DESCRIPTION OF THE EXAMPLE EMBODIMENTS

Hereinafter, example embodiments of the present disclosure will be described in detail with reference to the drawings. Example embodiments to be described below each indicate a comprehensive or specific example. Numeric values, shapes, materials, components, arrangement of the components, connection configurations, and the like described in the following example embodiments are exemplary and are not intended to limit the present invention.

Each of the drawings is schematically illustrated by appropriately adjusting ratios, emphasizing, or omitting for illustrating the present invention and is not necessarily precisely illustrated. The shapes, positional relationships, and ratios may be different from the actual shapes, positional relationships, and ratios. In each of the drawings, the same or corresponding components are denoted by the same reference numerals, and duplicate descriptions thereof may be omitted or simplified.

Furthermore, the terms representing the relationships between the components such as “parallel”, “vertical”, and so forth, the terms representing the shapes of the components such as “rectangular”, and ranges of values refer not only to exact meanings but also to substantially the same ranges, for example, errors of a few percent or several percent.

In the present disclosure, a “terminal” means a point where the conductor in a component ends. When the impedance of the conductor between components is sufficiently low, the terminal is interpreted as not only a single point but also any point on the conductor between the elements or the entirety of the conductor between the components.

In the present disclosure, a pass band of a filter refers to a portion of a frequency spectrum transmitted by the filter and is defined as a frequency band between two frequencies at which the power insertion loss is about 3 dB greater than the minimum value.

In the present disclosure, a “main ingredient of a material” refers to an ingredient the rate of which in the material exceeds 50% in weight. The above-described main ingredient may exist in, for example, a monocrystal state, a polycrystalline state, in an amorphous state, or a state in which these states coexist.

In a layered structure of the present disclosure, “an A layer (or a component A) is disposed on a main surface C of a B layer” refers to, in addition to a structure in which the A layer (or the component A) is disposed while in contact with the main surface C of the B layer, a structure in which the layer A (or the component A) is disposed above the main surface C without being in contact with the main surface C (for example, the layer A (or the component A) is laminated on another layer disposed so as to be in contact with the main surface C.

The structure of an acoustic wave device 1 according to an example embodiment of the present invention is described.

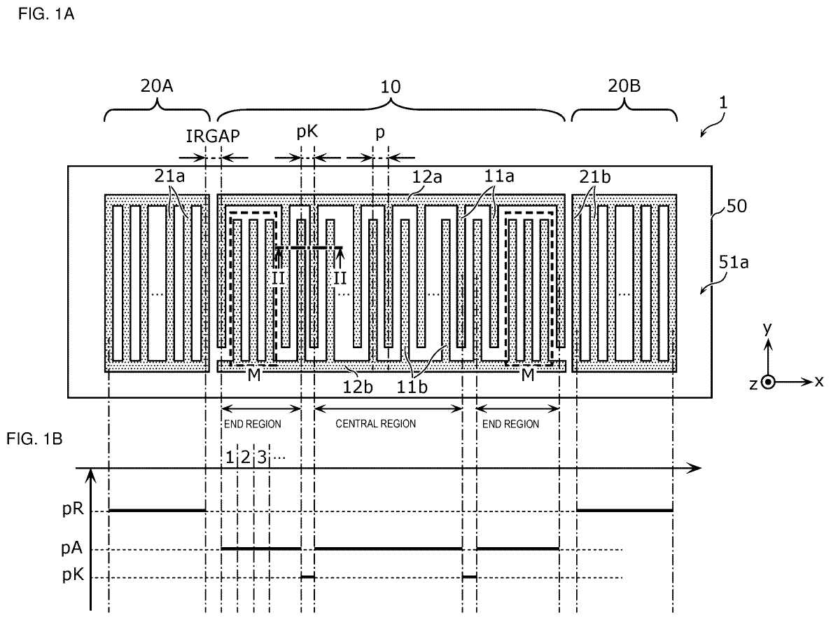

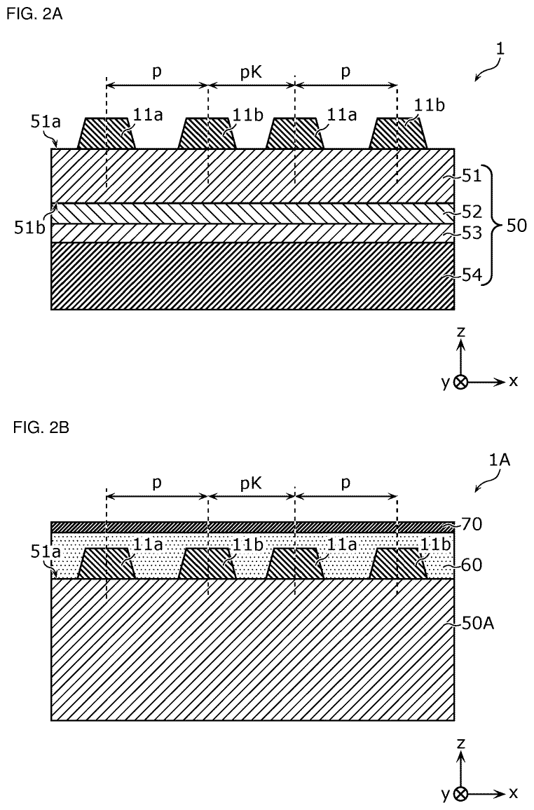

FIGS. 1A and 1B are plan views of the acoustic wave device 1 according to the present example embodiment. FIG. 2A is a sectional view of the acoustic wave device 1 according to the present example embodiment. In FIG. 1A, an electrode structure of the acoustic wave device 1 is illustrated. In FIG. 1B, a pitch distribution of electrode fingers is illustrated. FIG. 2A is a sectional view taken along line II-II illustrated in FIG. 1A. The acoustic wave device 1 illustrated in FIGS. 1A and 1B is for explaining a typical structure of the acoustic wave device 1. The number, length, and the like of the electrode fingers included in electrodes are not limited to these.

As illustrated in FIGS. 1A, 1B, and 2A, the acoustic wave device 1 includes a piezoelectric substrate 50, an interdigital transducer (IDT) electrode 10, and reflector electrodes 20A and 20B. The acoustic wave device 1 defines and functions as a surface acoustic wave (SAW) resonator.

The IDT electrode 10 and the reflector electrodes 20A and 20B have, for example, a laminated structure including an adhesion layer and a main electrode layer. The adhesion layer is a layer to improve adhesion between the piezoelectric substrate 50 and the main electrode layer, and is made of, for example, Ti. The main electrode layer is made of, for example, Al including a Cu content of about 1%. Although it is not illustrated in FIG. 2A, a protective film may be provided so as to cover the IDT electrode 10 and the reflector electrodes 20A and 20B. The protective film is a layer intended to protect the main electrode layer from the external environment, adjust frequency-temperature characteristics, and improve moisture resistance. A main ingredient of the protective film is, for example, silicon dioxide (SiO₂). The materials of the adhesion layer, the main electrode layer, and the protective film are not limited to the materials described above.

The IDT electrode 10 and the reflector electrodes 20A and 20B do not necessarily have the above-described laminated structure. Each of the IDT electrode 10, the reflector electrode 20A, and the reflector electrode 20B include metal such as, for example, Ti, Al, Cu, Pt, Au, Ag, or Pd or an alloy of the metal or includes a plurality of laminated bodies including the above-described metal or the alloy.

As illustrated in FIG. 2A, the piezoelectric substrate 50 has piezoelectricity and includes a piezoelectric layer 51, a low acoustic velocity layer 52, a high acoustic velocity layer 53, and a support substrate 54.

The piezoelectric layer 51 includes a main surface 51a (first main surface) and a main surface 51b (second main surface) that are opposite from each other. The IDT electrode 10 and the reflector electrodes 20A and 20B are disposed on the main surface 51a. The piezoelectric layer 51 may be made of, for example, lithium tantalate, lithium niobate, or a material which includes lithium tantalate or lithium niobate as the main ingredient.

The support substrate 54 is disposed on the main surface 51b side of the piezoelectric layer 51 and supports the IDT electrode 10, the reflector electrodes 20A and 20B, the piezoelectric layer 51, the low acoustic velocity layer 52, and the high acoustic velocity layer 53. The support substrate 54 can be made of, for example, a piezoelectric body such as silicon, aluminum nitride, lithium tantalate, lithium niobate, or crystal, ceramic such as alumina, sapphire, magnesia, silicon nitride, silicon carbide, zirconia, cordierite, mullite, steatite, or forsterite, dielectric such as diamond or glass, a semiconductor such as gallium nitride, resin, or a material which includes any of the above-described materials as the main ingredient.

The low acoustic velocity layer 52 is disposed between the piezoelectric layer 51 and the support substrate 54. The acoustic velocity of the bulk wave propagating through the low acoustic velocity layer 52 is lower than the acoustic velocity of the bulk wave propagating through the piezoelectric layer 51 and the support substrate 54. Due to this structure and the property that energy is concentrated to a medium where the speed of the acoustic wave is essentially low, leakage of the surface acoustic wave energy to the outside of the IDT electrode 10 is reduced or prevented. The low acoustic velocity layer 52 can be made of, for example, dielectric such as silicon oxide, glass, oxynitride silicon, lithium oxide, tantalum oxide, or a chemical compound made by adding fluorine, carbon, or boron to silicon oxide or a material which includes any of the above-described material as the main ingredient.

The high acoustic velocity layer 53 is disposed between the low acoustic velocity layer 52 and the support substrate 54. The acoustic velocity of the bulk wave propagating through the high acoustic velocity layer 53 is higher than the acoustic velocity of the bulk wave propagating through the low acoustic velocity layer 52. The high acoustic velocity layer 53 can be made of, for example, a piezoelectric body such as silicon nitride, aluminum nitride, lithium tantalate, lithium niobate, or crystal, ceramic such as alumina, sapphire, magnesia, silicon carbide, zirconia, cordierite, mullite, steatite, or forsterite, dielectric such as diamond or glass, a semiconductor such as silicon or gallium nitride, resin, or a material which includes any of the above-described materials as the main ingredient.

With the above-described laminated structure of the piezoelectric substrate 50, compared to the related-art structure including the single-layer piezoelectric substrate, the Q-value can be significantly improved in a resonant frequency and an anti-resonant frequency. That is, because an acoustic wave device having a high Q-value can be configured, an acoustic wave filter with a small insertion loss can be configured with this acoustic wave device. Furthermore, the frequency-temperature characteristics can be improved.

The high acoustic velocity layer 53 and the support substrate 54 may be integrated into a single high acoustic velocity support substrate. In the high acoustic velocity support substrate, the acoustic velocity of the bulk wave therein is higher than the acoustic velocity of acoustic waves such as a surface acoustic wave and a boundary wave propagating through the piezoelectric layer 51. The high acoustic velocity support substrate defines and functions so as to trap the surface acoustic wave within a portion where the piezoelectric layer 51 and the low acoustic velocity layer 52 are laminated and prevent the surface acoustic wave from leaking to a region below the high acoustic velocity support substrate. The high acoustic velocity support substrate can be made of, for example, a piezoelectric body such as aluminum nitride, lithium tantalate, lithium niobate, or crystal, ceramic such as alumina, sapphire, magnesia, silicon nitride, silicon carbide, zirconia, cordierite, mullite, steatite, forsterite, spinel, or sialon, dielectric such as aluminum oxide, oxynitride silicon, diamond-like carbon (DLC), or diamond, a semiconductor such as silicon, or a material which includes any of the above-described materials as the main ingredient. The above-described spinel includes, for example, an aluminum compound including oxygen and at least one element of Mg, Fe, Zn, Mn, or the like. Examples of the above-described spinel include MgAl₂O₄, FeAl₂O₄, ZnAl₂O₄, or MnAl₂O₄.

Furthermore, instead of the piezoelectric substrate 50, a structure formed by laminating the support substrate, an energy trapping layer, and the piezoelectric layer in this order may be provided.

The energy trapping layer includes a single layer or a plurality of layers, and the velocity of the bulk acoustic wave propagating through at least one of the layers is higher than the velocity of the acoustic wave propagating example, the energy trapping layer may have a laminated structure including a low acoustic velocity layer and a high acoustic velocity layer. The low acoustic velocity layer is a film in which the acoustic velocity of the bulk wave therein is lower than the acoustic velocity of the acoustic wave propagating through the piezoelectric layer. The high acoustic velocity layer is a film in which the acoustic velocity of the bulk wave therein is higher than the acoustic velocity of the acoustic wave propagating through the piezoelectric layer. The support substrate may be a high acoustic velocity layer.

Furthermore, the energy trapping layer may be an acoustic impedance layer having a structure formed by alternately laminating low acoustic impedance layers with a relatively low acoustic impedance and high acoustic impedance layers with a relatively high acoustic impedance.

Furthermore, a gap may be provided between the piezoelectric layer and the support substrate instead of the energy trapping layer. This enables the acoustic wave device 1 to define and function as a laterally excited bulk acoustic resonator (XBAR).

Furthermore, the piezoelectric substrate 50 may be a piezoelectric substrate 50A made of a piezoelectric monocrystal, for example. FIG. 2B is a sectional view of an acoustic wave device 1A according to a modification of the present example embodiment. As illustrated in FIG. 2B, the acoustic wave device 1A according to the present modification includes the piezoelectric substrate 50A, the IDT electrode 10, the reflector electrodes 20A and 20B, an insulator layer 60, and a dielectric layer 70. The acoustic wave device 1A according to the present modification differs from the acoustic wave device 1 according to the present example embodiment in that, in the acoustic wave device 1A, the piezoelectric substrate 50A is provided instead of the piezoelectric substrate 50 and the insulator layer 60 and the dielectric layer 70 are added to the acoustic wave device 1A. Hereinafter, description is focused on configurations different from those of the acoustic wave device 1 according to the example embodiment.

The piezoelectric substrate 50A is an example of the piezoelectric substrate, includes a main surface 51a, and is made of a piezoelectric monocrystal. The piezoelectric substrate 50A is a monocrystal piezoelectric substrate made of, for example, lithium niobate. The piezoelectric substrate 50A may bea monocrystal piezoelectric substrate made of lithium tantalate, crystal, or potassium nitride, for example. The IDT electrode 10 and the reflector electrodes 20A and 20B are disposed on the main surface 51a.

The insulator layer 60 covers the main surface 51a, the IDT electrode 10, and the reflector electrodes 20A and 20B and allow the IDT electrode 10 to be embedded therein. In other words, the insulator layer 60 is disposed from the main surface 51a to a position close to an upper surface of the IDT electrode 10. The insulator layer 60 is a layer including, for example, silicon dioxide (SiO₂) as the main ingredient. With the disposition and the configuration of the insulator layer 60, the frequency-temperature characteristics of the acoustic wave device 1A can be improved.

The dielectric layer 70 covers the insulator layer 60. The dielectric layer 70 is a layer including, for example, the material the same as or similar to the material of the high acoustic velocity layer 53 as the main ingredient. The dielectric layer 70 is not necessarily provided.

Next, the configuration of the electrode fingers of the IDT electrode 10 and the reflector electrodes 20A and 20B is described.

As illustrated in FIG. 1A, the IDT electrode 10 includes a pair of comb electrodes disposed on the piezoelectric substrate 50 so as to face each other. One of the pair of comb electrodes includes a plurality of comb electrode fingers 11a and a busbar electrode 12a. The plurality of comb electrode fingers 11a are disposed so as to extend in a second direction (y axis direction) intersecting a first direction (x axis direction) that is an acoustic wave propagating direction. The busbar electrode 12a connects respective ends of the plurality of comb electrodes 11a to each other. Another of the pair of comb electrodes includes a plurality of comb electrode fingers 11b and a busbar electrode 12b. The plurality of comb electrode fingers 11b are disposed so as to extend in the second direction (y axis direction). The busbar electrode 12b connects respective ends of the plurality of comb electrodes 11b to each other. Electrode fingers of the plurality of comb electrode fingers 11a and the plurality of comb electrode 11b are alternately arranged in the first direction.

The reflector electrodes 20A and 20B are disposed on the piezoelectric substrate 50 so as to be adjacent to the IDT electrode 10 in the first direction. The reflector electrode 20A includes a plurality of reflector electrode fingers 21a disposed so as to extend in the second direction. The reflector electrode 20B includes a plurality of reflector electrode fingers 21b disposed so as to extend in the second direction.

Among the plurality of comb electrode fingers 11a and 11b, the comb electrode finger closest to the reflector electrode 20A is defined as a first end-side electrode finger, and the comb electrode fingers arranged in a direction from the first end-side electrode finger toward the center of the IDT electrode 10 are sequentially defined as nth end-side electrode fingers (n is natural numbers). Furthermore, among the plurality of comb electrode fingers 11a and 11b, the comb electrode finger closest to the reflector electrode 20B is defined as a first end-side electrode finger, and the comb electrode fingers arranged in a direction from the first end-side electrode finger toward the center of the IDT electrode 10 are sequentially defined as nth end-side electrode fingers (n is natural numbers).

Furthermore, among the electrode fingers included in the reflector electrodes 20A and 20B, a center-to-center distance in the first direction between the electrode fingers adjacent to each other in the first direction is defined as a pitch, and a pitch between the nth end-side electrode finger and the (n+1)th end-side electrode finger is defined as an nth end-side pitch. Here, among the pitches arranged from the first end-side electrode finger to the comb electrode finger positioned in the center of the IDT electrode 10, the mth end-side pitch is smaller than an average pitch pA of pitches of the plurality of comb electrode fingers 11a and 11b except for the mth end-side pitch. Hereinafter, the mth end-side pitch is referred to as a narrow pitch (pk). The mth end-side pitch may be the smallest of the nth end-side pitches in the IDT electrode 10.

As illustrated in FIG. 1A, when the main surface 51a is seen in plan view, in a region where the IDT electrode 10 is provided, regions from the first end-side electrode finger to the mth end-side electrode fingers having the narrow pitch are defined as end regions. Two end regions are provided at the ends of the IDT electrode 10 in the first direction, and a region interposed between the two end regions is defined as a central region.

Here, the IDT electrode 10 includes thinned electrodes M disposed in the end regions. Here, a thinned electrode M is defined as follows. Examples of the thinned electrode include (1) a polarity-inverted thinned electrode, (2) a floating thinned electrode, and (3) a solid-fill thinned electrode.

The polarity-inverted thinned electrode is a comb electrode finger connected to the same busbar electrode as that to which the adjacent comb electrode fingers on both sides are connected. A thinning rate of the IDT electrode including the polarity-inverted thinned electrode in a predetermined region is defined as follows. When the number of the polarity-inverted thinned electrodes in the predetermined region is defined as X, a pair of the adjacent comb electrode fingers 11a and 11b are defined as a single pair of electrode fingers, and the number of such pairs in the predetermined region is defined as W assuming that, in the predetermined region, only the comb electrode fingers 11a and 11b are repeatedly provided without providing the polarity-inverted thinned electrode, the thinning rate of the predetermined region is given by expression 1. In calculating the thinning rate, three comb electrode fingers including the polarity-inverted comb electrode finger and the adjacent comb electrode fingers on both sides are defined as a single thinned electrode.

$$Thinning rate = X / \{ 2 ( W - X ) + 1 \} . \qquad Expression 1$$

The floating thinned electrode is a comb electrode finger connected to neither the busbar electrode 12a nor the busbar electrode 12b that face each other. A thinning rate of the IDT electrode including the floating thinned electrode in a predetermined region is defined as follows. When the number of the floating thinned electrodes in the predetermined region is defined as X, a pair of the adjacent comb electrode fingers 11a and 11b are defined as a single pair of electrode fingers, and the number of such pairs in the predetermined region is defined as W assuming that, in the predetermined region, only the comb electrode fingers 11a and 11b are repeatedly provided without providing the floating thinned electrode, the thinning rate of the predetermined region is given by expression 1. In calculating the thinning rate, three comb electrode fingers including the comb electrode finger connected to neither the busbar electrode 12a nor the busbar electrode 12b and the adjacent comb electrode fingers on both sides are defined as a single thinned electrode.

The solid-fill thinned electrode is an electrode finger having the maximum electrode finger width in the IDT electrode 10. The solid-fill thinned electrode is a comb electrode finger having the electrode finger width that is greater than or equal to about twice an average electrode finger width of the comb electrode fingers other than the solid-fill thinned electrode. A thinning rate of the IDT electrode including the solid-fill thinned electrode in a predetermined region is defined as follows. When the number of the solid-fill thinned electrodes in the predetermined region is defined as X, a pair of the adjacent comb electrode fingers 11a and 11b are defined as a single pair of electrode fingers, and the number of such pairs in the predetermined region is defined as W assuming that, in the predetermined region, only the comb electrode fingers 11a and 11b are repeatedly provided without providing the solid-fill thinned electrode, the thinning rate of the predetermined region is given by expression 1. In calculating the thinning rate, the comb electrode finger having the maximum electrode finger width is regarded as a single thinned electrode.

Furthermore, in a boundary region between the IDT electrode 10 and the reflector electrode 20A (or 20B), the distance in the first direction between the center of the comb electrode finger closest to the reflector electrode 20A (or 20B) among the plurality of comb electrode fingers 11a and 11b and the center of the reflector electrode finger closest to the IDT electrode 10 among the plurality of reflector electrode fingers 21a (or 21b) is defined as an IDT-reflector electrode gap (hereinafter, referred to as an IRGAP).

Here, a wavelength λ and a pitch p are defined.

The wavelength λ of the IDT electrode 10 is a unit of the length defined by a cycle period of the comb electrode finger 11a (or 11b). Furthermore, the electrode finger pitch p of the IDT electrode 10 is about ½ of the wavelength λ. Furthermore, the pitch p of the reflector electrode 20A (or 20B) is a unit of the length defined by a cycle period of the reflector electrode finger 21a (or 21b).

When the distances between the adjacent comb electrode fingers in the IDT electrode 10 vary, the wavelength λ of the IDT electrode 10 is defined as an average wavelength AA of the IDT electrode 10. The average wavelength AA of the IDT electrode 10 is defined as 2×Di/(Ni−1), where Ni is a total number of the comb electrode fingers 11a and 11b included in the IDT electrode 10, and Di is a center-to-center distance between the comb electrode finger positioned at one end and the comb electrode finger positioned at the other end of the IDT electrode 10 in the first direction. However, the number of the mth end-side electrode fingers is subtracted from the total number Ni, and the mth end-side pitch is subtracted from the center-to-center distance Di. The average pitch pA of the IDT electrode 10 is about ½ of the average wavelength λA.

When the IDT electrode 10 includes the thinned electrode, in calculating the average wavelength λA, as the total number Ni of the electrode fingers, the number of the thinned electrodes is excluded, and as the center-to-center distance Di, a line width L of the thinned electrode and one of two spaces (space width S) adjacent to the thinned electrode are excluded.

When the IDT electrode 10 has a 2D piston structure and the electrode finger width at a tip end portion of the comb electrode finger is greater than that at a central portion of the comb electrode finger, the wavelength λ is defined as a wavelength at the central portion of the comb electrode finger. When the IDT electrode 10 has the 2D piston structure but it cannot be said that the electrode finger width at the tip end portion of the comb electrode finger is greater than that at the central portion of the comb electrode finger, the wavelength λ is defined as an average wavelength in a range from which both ends of an intersecting width region of the comb electrode finger is excluded. When the electrode finger width varies periodically in the intersecting width direction of the comb electrode finger, the wavelength λ is defined as an average wavelength in the intersecting width region of the comb electrode finger.

When the distances between the adjacent reflector electrode fingers in the reflector electrode 20A (or 20B) vary, the pitch p of the reflector electrode 20A (or 20B) is defined as an average pitch pR of the reflector electrode 20A (or 20B). The average pitch pR of the reflector electrode 20A (or 20B) is defined as 2×Di/(Ni−1), where Ni is the total number of the reflector electrode fingers 21a (or 21b) included in the reflector electrode 20A (or 20B), and Di is a center-to-center distance between a reflector electrode finger located at one end and a reflector electrode finger located at the other end of the reflector electrode 20A (or 20B) in the first direction.

The wavelength λ and pitch p of the IDT electrode 10 and the pitch p of the reflector electrodes 20A and 20B can be measured by, for example, observing and measuring the main surface 51a of the piezoelectric layer 51 in plan view and/or the section perpendicular to an extending direction of the electrode fingers (second direction) in sectional view, using a scanning electron microscope (SEM), a scanning transmission electron microscope (STEM), or a transmission electron microscope (TEM).

Configurations of the electrode fingers appropriate for the acoustic wave device 1 according to the present example embodiment are described by comparing acoustic wave devices according to examples of example embodiment of the present invention and acoustic wave devices according to comparative examples in the reflection characteristics and the impedance characteristics.

Table 1 indicates main electrode parameters of the acoustic wave devices according to comparative examples 1 to 7. Table 2 indicates main electrode parameters of the acoustic wave devices according to examples 1 to 15. Referring to Tables 1 and 2, λ_{IDT} indicates the wavelength λ of the IDT electrode 10, and λ_{REF} indicates the wavelength λ of the reflector electrodes 20A and 20B.

TABLE 1

| | Comparative | Comparative | Comparative | Comparative | Comparative | Comparative | Comparative |
|---|---|---|---|---|---|---|---|
| | example 1 | example 2 | example 3 | example 4 | example 5 | example 6 | example 7 |
| Narrow pitch | — | m = 7 | m = 7 | m = 21 | m = 21 | 0.90 pA | m = 6 |
| | | 0.9 pA | 0.9 pA | 0.96 pA | 0.96 pA | | 0.92 pA |
| Thinned | — | — | non- | — | non- | — | — |
| electrode M | | | periodic | | periodic | | |
| (polarity- | | | 4% | | 4% | | |
| inverted) | | | | | | | |
| λ_{REF}/λ_{IDT} | 1.0 | 1.045 | 1.045 | 1.045 | 1.045 | 1.060 | 1.060 |
| IRGAP/λ_{REF} | 0.5 | 0.5 | 0.5 | 0.4 | 0.4 | 0.5 | 0.4 |

TABLE 2

| | Example | Example | Example | Example | Examples | Examples | Example |
|---|---|---|---|---|---|---|---|
| | 1 | 2 | 3 | 4 | 5 to 9 | 10 to 14 | 15 |
| Narrow pitch | m = 7 | m = 21 | m = 21/24 | m = 21 | 0.96 pA | 0.90 to | m = 26 |
| | 0.9 pA | 0.96 pA | 0.96 pA | 0.96 pA | | 0.98 pA | 0.97 pA |
| Thinned | End 4% | End 4% | End + | End + | End 3 | End 1 to 5 | End 4 |
| electrode M | | | End | Center | | | |
| (polarity- | | | | | | | |
| inverted) | | | | | | | |
| λ_{REF}/λ_{IDT} | 1.045 | 1.045 | 1.045 | 1.045 | 1.045 | 1.060 | 1.060 |
| IRGAP/λ_{REF} | 0.5 | 0.4 | 0.4 | 0.4 | 0.4 | 0.37 to | 0.4 |
| | | | | | | 0.5 | |

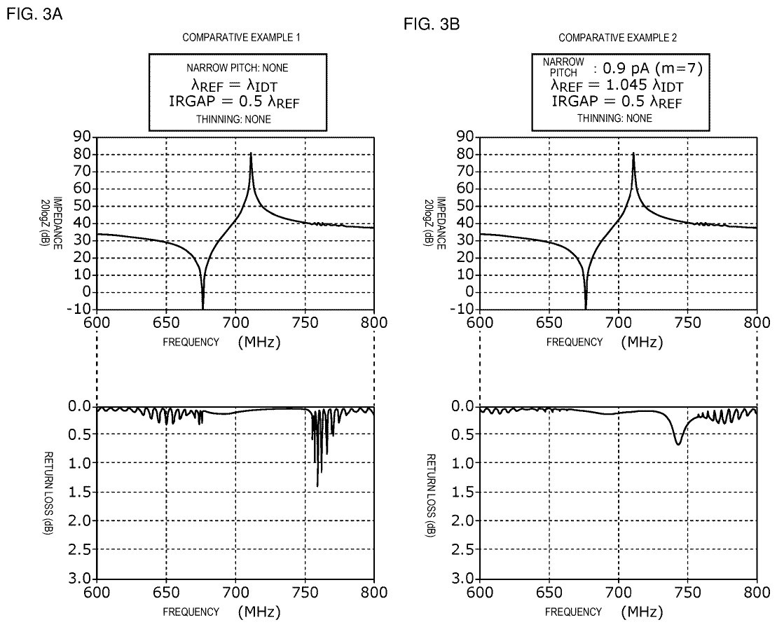

FIGS. 3A and 3B include graphs illustrating the impedance characteristics and the reflection characteristics of the acoustic wave devices according to comparative examples 1 and 2. In the acoustic wave device according to comparative example 1, the IDT electrode includes neither the narrow pitch nor the thinned electrode. In the acoustic wave device according to comparative example 2, the IDT electrode includes the narrow pitch (m=7, pK=0.9 pA) but does not include the thinned electrode.

As illustrated in FIG. 3A, in the acoustic wave device according to comparative example 1, ripples due to a longitudinal mode (hereinafter, may be referred to as longitudinal mode ripples) are generated in a band close to a low-frequency side of the anti-resonant frequency, and ripples are generated at a high-frequency end of a stop band (hereinafter, may be referred to as stop band ripples) in a band close to a high-frequency side of the anti-resonant frequency. In contrast, as illustrated in FIG. 3B, with the acoustic wave device according to comparative example 2, the longitudinal mode ripples and the stop band ripples reduce due to disposition of the narrow pitch. However, no thinned electrode is disposed in the acoustic wave devices according to comparative example 1 and comparative example 2. Thus, a fractional bandwidth (a value obtained by dividing a difference frequency of an anti-resonant frequency and a resonant frequency by the resonant frequency) does not vary. That is, only the narrow pitch reduces ripples close to the e band but cannot adjust the fractional bandwidth.

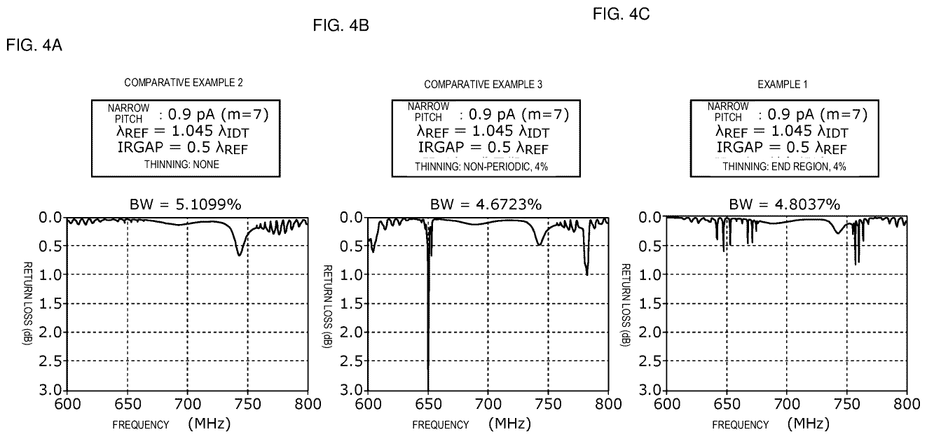

FIGS. 4A to 4C include graphs illustrating the reflection characteristics of the acoustic wave devices according to comparative examples 2 and 3 and example 1. In the acoustic wave device according to comparative example 2, the IDT electrode includes the narrow pitch (for example, m=7, pK=0.9 pA) but does not include the thinned electrode. In the acoustic wave device according to comparative example 3, the IDT electrode includes the narrow pitch (for example, km=7, pK=0.9 pA) and the thinned electrode (non-periodic, thinning rate of about 4%). In the acoustic wave device according to example 1, the IDT electrode includes the narrow pitch (for example, m=7, pK=0.9 pA) and the thinned electrode (disposed at the end region, thinning rate of about 4%).

When comparing FIGS. 4A and 4B, with the acoustic wave device according to comparative example 3, relative to the acoustic wave device according to comparative example 2, the fractional bandwidth reduces due to the location of the thinned electrode but ripples close to the resonance band do not reduce. In contrast, with the acoustic wave device according to example 1, relative to the acoustic wave device according to comparative example 3, ripples close to the resonance band reduce due to the location of the thinned electrode in the end region. Although it is not illustrated, with acoustic wave resonators according to comparative example 3 and example 1, the fractional bandwidth reduces relative to that of the acoustic wave device according to comparative example 2.

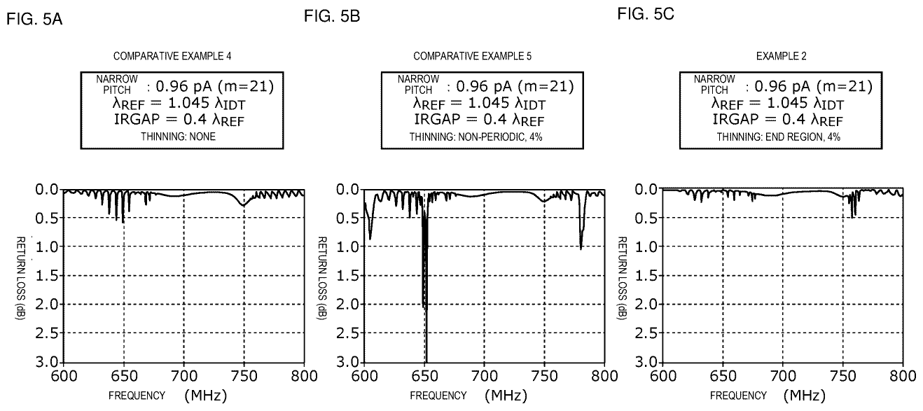

FIGS. 5A to 5C include graphs illustrating the reflection characteristics of the acoustic wave devices according to comparative examples 4 and 5 and example 2. In the acoustic wave device according to comparative example 4, the IDT electrode includes the narrow pitch (for example, m=21, pK=0.96 pA) but does not include the thinned electrode. In the acoustic wave device according to comparative example 5, the IDT electrode includes the narrow pitch (for example, m=21, pK=0.96 pA) and the thinned electrode (non-periodic, thinning rate of about 4%). In the acoustic wave device according to example 2, the IDT electrode includes the narrow pitch (for example, m=21, pK=0.96 pA) and the thinned electrode (disposed at the end region, thinning rate of about 4%). In the acoustic wave devices according to comparative examples 4 and 5 and example 2 illustrated in FIGS. 5A to 5C, relative to the acoustic wave devices according to comparative examples 2 and 3 and example 1 illustrated in FIGS. 4A to 4C, the narrow pitch is disposed closer to the center of the IDT electrode, the narrow pitch pk is increased, and the IRGAP is reduced.

When comparing FIGS. 5A and 5B, with the acoustic wave device according to comparative example 5, relative to the acoustic wave device according to comparative example 4, the fractional bandwidth reduces due to the location of the thinned electrode but ripples close to the resonance band do not reduce. In contrast, with the acoustic wave device according to example 2, relative to the acoustic wave device according to comparative example 4, ripples close to the resonance band reduce due to the location of the thinned electrode in the end region. Although it is not illustrated, with the acoustic wave resonators according to comparative example 5 and example 2, the fractional bandwidth reduces relative to that of the acoustic wave device according to comparative example 4.

With the acoustic wave device according to example 2, the thinned electrode is disposed in the end region of the IDT electrode. This enables reduction of ripples close to the resonance band (resonant frequency) and adjustment of the fractional bandwidth (resonance bandwidth).

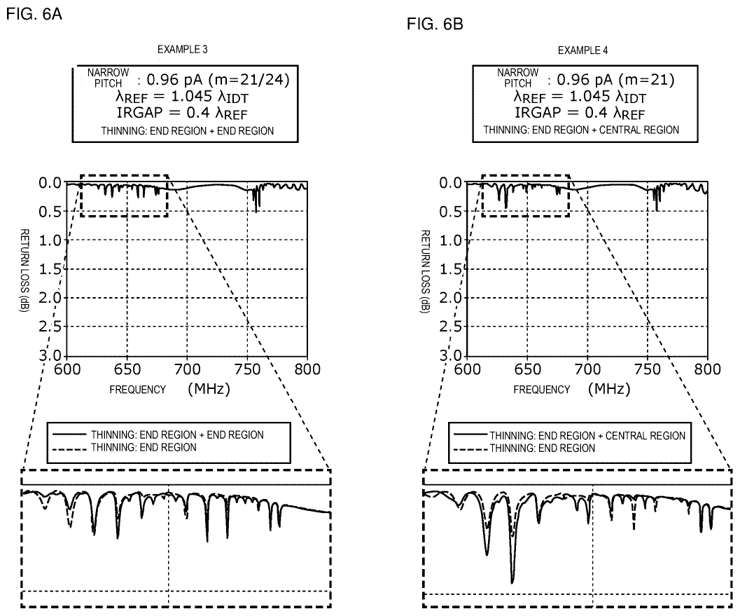

FIGS. 6A and 6B include graphs illustrating the reflection characteristics of the acoustic wave devices according to examples 3 and 4. In the acoustic wave device according to example 3, the IDT electrode includes, on one side, two narrow pitches (for example, m=21 and m=24, pK=0.96 pA) and the thinned electrodes (two at the end region). In the acoustic wave device according to example 3, the IDT electrode include no thinned electrode in the central region. In the acoustic wave device according to example 4, the IDT electrode includes, on one side, a single narrow pitch (for example, m=21, pK=0.96 pA) and the thinned electrodes (one in the end region and one in the central region).

As illustrated in FIG. 6B, compared to the case where one thinned electrode is disposed only in the end region, the acoustic wave device according to example 4 does not reduce ripples on the low-frequency side of the resonance band. In contrast, to the same degree as the case where one thinned electrode is disposed in the end region, the acoustic wave device according to example 3 can reduce ripples on the low-frequency side of the resonance band and adjust the fractional bandwidth.

With the acoustic wave device according to examples 3 and 4, the thinned electrodes are concentrated in the end region, and no thinned electrode is disposed in the central region. This enables further reduction of ripples close to the resonance band (resonant frequency) and adjustment of the fractional bandwidth (resonance bandwidth).

In the acoustic wave resonator according to the present example embodiment, the IDT electrode 10 may include a plurality of thinned electrodes disposed in the end region and at least one thinned electrode disposed in the central region, and the thinning rate of the end region may be higher than the thinning rate of the central region.

Thus, the thinned electrodes are distributed more in the end region than in the central region, and accordingly, ripples close to the resonance band (resonant frequency) can be further reduced and the fractional bandwidth (resonance bandwidth) can be adjusted.

As is the case with the acoustic wave device according to example 3, the acoustic wave device 1 according to the present example embodiment may include a plurality of narrow pitches in one end region.

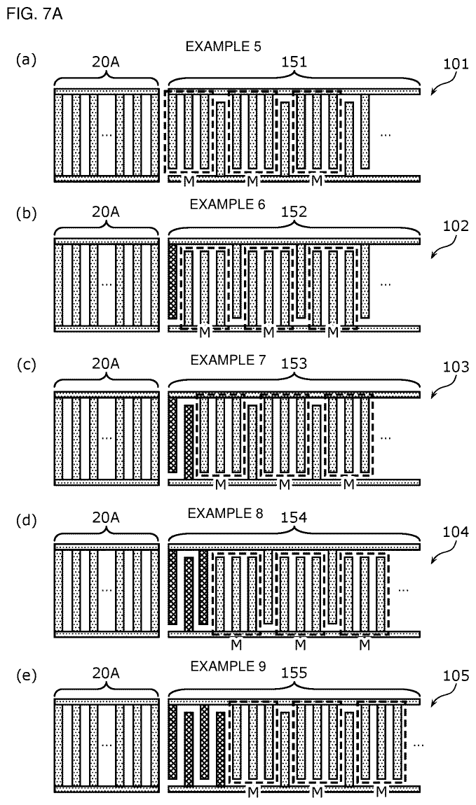

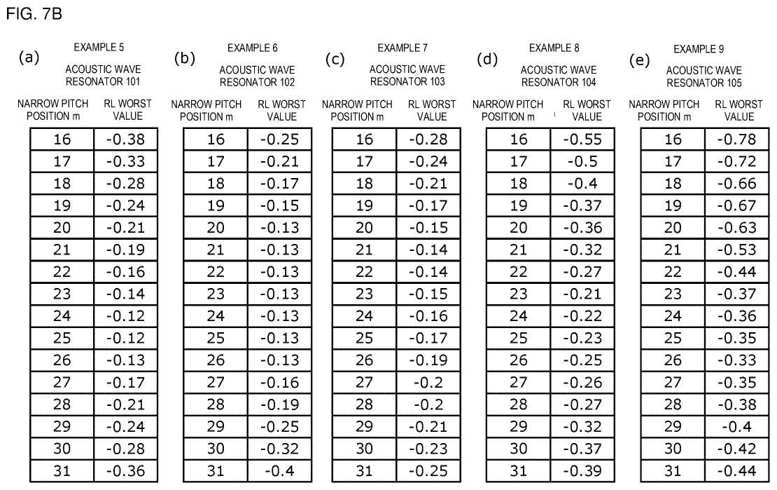

FIG. 7A includes plan views schematically illustrating configurations of the electrodes of acoustic wave devices 101 to 105 according to examples 5 to 9. In the acoustic wave devices 101 to 105 according to examples 5 to 9, regarding IDT electrodes 151 to 155, three thinned electrodes disposed in one of the end regions are included in each of the IDT electrode 151 to 155. Here, the polarity-inverted thinned electrode is illustrated as the example. A single thinned electrode is defined by three comb electrode fingers including the polarity-inverted comb electrode finger and the adjacent comb electrode fingers on both sides.

In example 5, no comb electrode finger is disposed between the reflector electrode 20A and three thinned electrodes, and the comb electrode finger is disposed between the reflector electrode 20B and three thinned electrodes. In example 6, a single comb electrode finger is disposed between the reflector electrode 20A and three thinned electrodes, and one comb electrode finger is disposed between the reflector electrode 20B and three thinned electrodes. In example 7, two comb electrode fingers are disposed between the reflector electrode 20A and three thinned electrodes, and two comb electrode fingers are disposed between the reflector electrode 20B and three thinned electrodes. In example 8, three comb electrode fingers are disposed between the reflector electrode 20A and three thinned electrodes, and three comb electrode fingers are disposed between the reflector electrode 20B and three thinned electrodes. In example 9, four comb electrode fingers are disposed between the reflector electrode 20A and three thinned electrodes, and four comb electrode fingers are disposed between the reflector electrode 20B and three thinned electrodes.

FIG. 7B illustrates the relationships between a narrow pitch position m and return loss (RL) of the acoustic wave devices according to examples 5 to 9. In FIG. 7B, an RL worst value indicates the minimum value of return loss (RL) of the longitudinal mode ripples generated close to the low-frequency side of the resonance band.

As illustrated in FIG. 7B, at narrow pitch positions m≥23, the RL worst value tends to reduce from the acoustic wave device 101 to acoustic wave device 105. In other words, at the narrow pitch positions m≥23, the RL worst value tends to reduce as the number of the comb electrode fingers disposed between the reflector electrode 20A (or 20B) and three thinned electrodes increases.

When an acoustic wave filter and a multiplexer including an acoustic wave device according to an example embodiment of the present invention are configured, the return loss of the acoustic wave device is preferably smaller than or equal to 0.3 dB (RL≥−0.3 dB). From the viewpoint of this, in the acoustic wave devices according to examples 5 to 8, the narrow pitch position m satisfying RL≥−0.3 dB exists. That is, the number of comb electrode fingers disposed between the reflector electrode 20A (or 20B) and the thinned electrode is greater than or equal to zero and smaller than or equal to three. In this way, the longitudinal mode ripples can be further reduced or prevented.

Furthermore, the longitudinal mode ripples can be further reduced or prevented when a plurality of thinned electrodes are concentrated in a region of the end region close to the reflector electrode 20A (or 20B). That is, when the end region is bifurcated into a first end region close to the reflector electrode 20A (or 20B) and a second end region close to the center in each of the IDT electrodes 151 to 155, the thinning rate is preferably higher in the first end region than in the second end region. In this way, the longitudinal mode ripples can be further reduced or prevented.

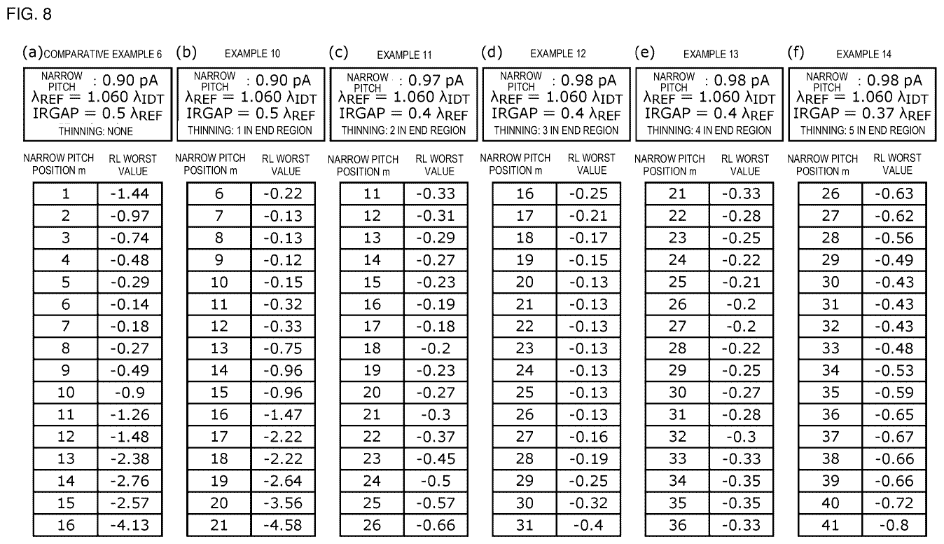

FIG. 8 illustrates the relationships between the narrow pitch position m and the return loss (RL) of the acoustic wave devices according to comparative example 6 and examples 10 to 14. In FIG. 8, the RL worst value indicates the minimum value of return loss (RL) of the longitudinal mode ripples generated close to the low-frequency side of the resonance band.

In the acoustic wave device according to comparative example 6, the IDT electrode includes the narrow pitch (for example, pK=0.90 pA) but does not include the thinned electrode. In the acoustic wave device according to example 10, the IDT electrode includes the narrow pitch (for example, pK=0.90 pA) and the thinned electrode (one in one end region). In the acoustic wave device according to example 11, the IDT electrode includes the narrow pitch (for example, pK=0.97 pA) and the thinned electrodes (two in one end region). In the acoustic wave device according to example 12, the IDT electrode includes the narrow pitch (for example, pK=0.98 pA) and the thinned electrodes (three in one end region). In the acoustic wave device according to example 13, the IDT electrode includes the narrow pitch (for example, pK=0.98 pA) and the thinned electrodes (four in one end region). In the acoustic wave device according to example 14, the IDT electrode includes the narrow pitch (for example, pK=0.98 pA) and the thinned electrodes (five in one end region).

In the acoustic wave devices according to examples 10 to 13, the narrow pitch position m satisfying RL≥−0.3 dB exists. That is, the number of thinned electrodes disposed in one end region is preferably greater than or equal to one and smaller than or equal to four. In this way, the longitudinal mode ripples can be further reduced or prevented.

In the acoustic wave device according to example 12, the range of the narrow pitch position m satisfying RL≥−0.3 dB is m≤29. In the acoustic wave device according to example 13, the range of the narrow pitch position m satisfying RL≥−0.3 dB is m≤32. That is, when the number of the thinned electrodes disposed in one end region is three or four, the narrow pitch is positioned with improved versatility.

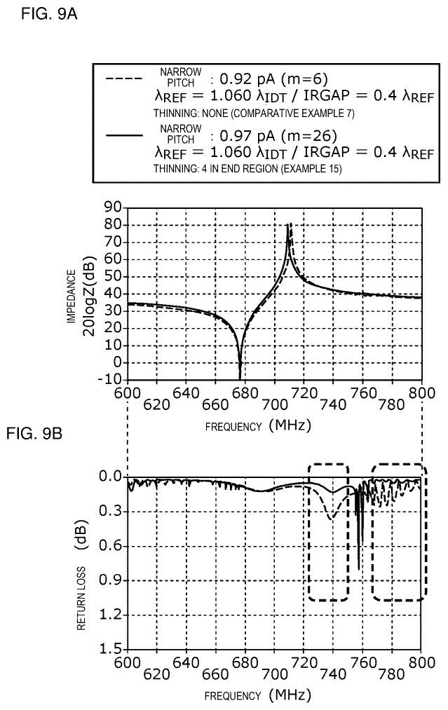

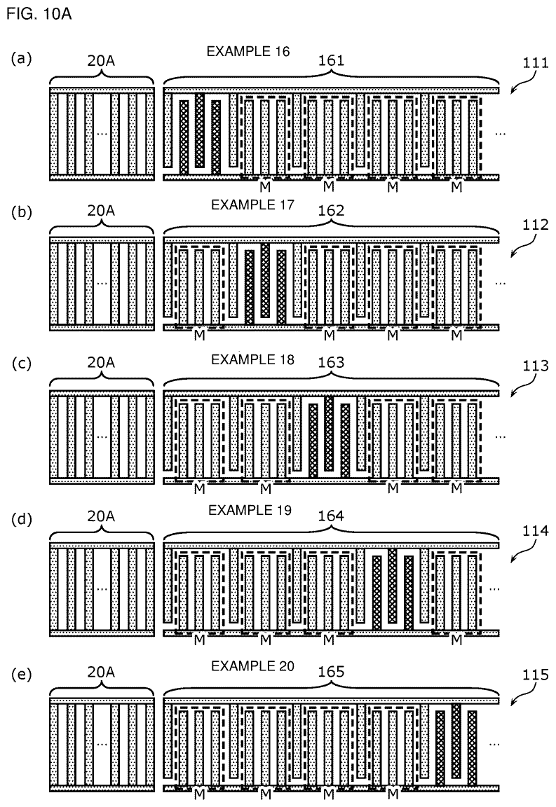

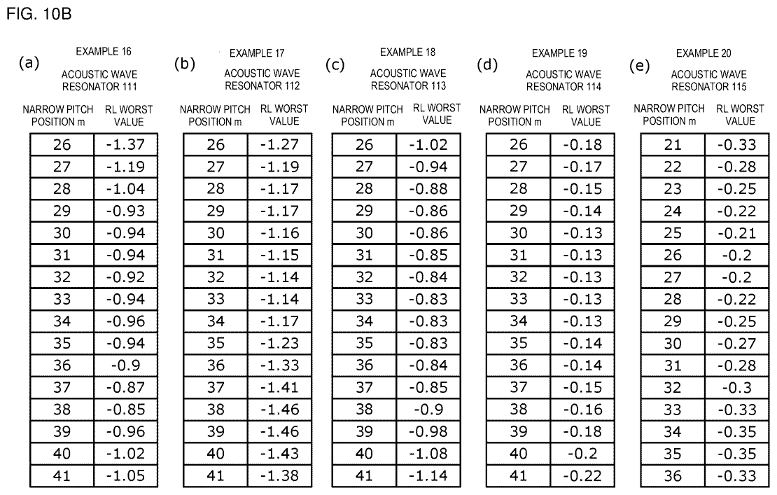

FIGS. 9A and 9B include graphs illustrating the impedance characteristics and the reflection characteristics of acoustic wave devices according to comparative example 7 and example 15. In the acoustic wave device according to comparative example 7, the IDT electrode includes the narrow pitch (m=6, pK=0.92 pA) and does not include the thinned electrode. In the acoustic wave device according to example 15, the IDT electrode includes the narrow pitch (for example, m=26, pK=0.97 pA) and the thinned electrodes (four in one end region).

In the acoustic wave device according to example 15, compared to the acoustic wave device according to comparative example 7, the longitudinal mode ripples reduce on the low-frequency side close to the resonant band and the fractional bandwidth reduces. Furthermore, the stop band ripples reduce on the high-frequency side close to the resonance band (in broken line boxes in FIG. 9B).

Thus, when four thinned electrodes are disposed in one end region and the narrow pitch position m, the wavelength λ of the reflector electrodes 20A and 20B, and the IRGAP are adjusted, the longitudinal mode ripples and the stop band ripples close to the resonance band can be reduced and the fractional bandwidth can be adjusted.

The IRGAP is preferably for example, smaller than 0.45×λ_{REF}. In this way, the stop band ripples can be further reduced on the high-frequency side close to the resonance band.

FIG. 10A includes plan views schematically illustrating configurations of the electrodes of acoustic wave device 111 to 115 according to examples 16 to 20. In the acoustic wave devices 111 to 115 according to examples 16 to 20, regarding IDT electrode 161 to 165, four thinned electrodes in one of the end regions are included in each of the IDT electrode 161 to 165. Here, the polarity-inverted thinned electrode is illustrated as the example. A single thinned electrode is defined by three comb electrode fingers including the polarity-inverted comb electrode finger and the adjacent comb electrode fingers on both sides.

In example 16, a plurality of the comb electrode fingers are disposed between the reflector electrode 20A and four thinned electrodes, and a plurality of comb electrode fingers are disposed between the reflector electrode 20B and four thinned electrodes. In example 17, a plurality of comb electrode fingers are disposed between the first and second thinned electrodes counted from the outermost side. In example 18, the plurality of comb electrode fingers are disposed between the second thinned electrodes counted from the outermost side. In example 19, the plurality of comb electrode fingers are disposed between the third and fourth thinned electrodes counted from the outermost side. In example 20, the plurality of comb electrode fingers are disposed close to the center of an IDT electrode 165 relative to the fourth thinned electrode counted from the outermost side.

FIG. 10B illustrates the relationships between the narrow pitch position m and return loss (RL) of the acoustic wave devices 111 to 115 according to examples 16 to 20. In FIG. 10B, the RL worst value indicates the minimum value of return loss (RL) of the longitudinal mode ripples generated close to the low-frequency side of the resonance band.

In the acoustic wave devices 114 and 115 according to examples 19 to 20, the narrow pitch position m satisfying RL≥−0.3 dB exists. That is, the longitudinal mode ripples can be further reduced or prevented when a plurality of thinned electrodes are concentrated in a region of the end region close to the reflector electrode 20A (or 20B). That is, when the end region is bifurcated into a first end region close to the reflector electrode 20A (or 20B) and a second end region close to the center in each of the IDT electrodes 161 to 165, the thinning rate is preferably higher in the first end region than in the second end region. In this way, the longitudinal mode ripples can be further reduced or prevented.

In the acoustic wave devices according to examples 1 to 20, the pitch of the comb electrode fingers of the IDT electrode may be randomly set. In the random pitch, the pitches are arranged such that the pitches irregularly increase or reduce. That is, the plurality of comb electrode fingers 11a and 11b are randomly disposed such that the pitches of the adjacent comb electrode fingers 11a and 11b irregularly change. The irregular change includes a state in which changes are randomly made without including a fixed state, a proportional change, and a periodical change. In this case, the mth end-side pitch is a minimum among the nth end-side pitches included in the IDT electrode (n is a natural number). When the random pitch is applied to the arrangement of the comb electrode fingers of the IDT electrode, the stop band ripples can be further reduced on the high-frequency side close to the resonance band.

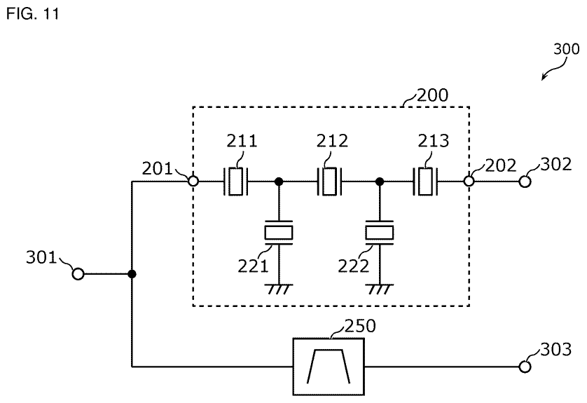

Next, circuit configuration examples of an acoustic wave filter 200 and a multiplexer 300 including an acoustic wave device 1 according to an example embodiment of the present invention are described. FIG. 11 is a circuit configuration diagram of the multiplexer 300 according to the present example embodiment. As illustrated in FIG. 11, the multiplexer 300 includes filters 200 and 250, a common terminal 301, and input and output terminals 302 and 303. The common terminal 301 is connected to, for example, an antenna.

The filter 200 is an example of an acoustic wave filter and connected between the common terminal 301 and the input and output terminal 302. The filter 200 is a ladder band pass filter and includes series-arm resonators 211, 212, and 213, parallel-arm resonators 221 and 222, and input and output terminals 201 and 202. At least one of the series-arm resonators 211 to 213 and the parallel-arm resonators 221 and 222 is the acoustic wave device 1 according to the example embodiment. It is sufficient that the filter 200 be an acoustic wave filter including the acoustic wave device 1 according to an example embodiment. The filter 200 is not necessarily a ladder band pass filter and may be, for example, an acoustic wave filter including the longitudinally coupled resonator.

The filter 250 is an example of a first filter and connected between the common terminal 301 and the input and output terminal 303. The filter 250 may be an acoustic wave filter, an LC filter, a dielectric filter, or the like. The filter 250 has any filter structure.

With the above-described configuration of the filter 200, the acoustic wave device 1 according to an example embodiment is included. Thus, a low-loss acoustic wave filter that can reduce or prevent ripples close to the pass band and allow the adjustment of the pass bandwidth can be provided.

With the above-described configuration of the multiplexer 300, the filter 200 including the acoustic wave device 1 is included. Thus, the multiplexer 300 that can enable the adjustment of the pass bandwidth of the filter 200 and reduce or prevent an insertion loss in the pass band of the filter 250 can be provided.

It is sufficient that at least two filters are included in the multiplexer 300.

As has been described, an acoustic wave device 1 according to an example embodiment includes the piezoelectric substrate 50, the IDT electrode 10 disposed on the piezoelectric substrate 50, and the reflector electrodes 20A and 20B disposed on the piezoelectric substrate 50 so as to be adjacent to the IDT electrode 10 in the first direction. The IDT electrode 10 includes a plurality of comb electrode fingers 11a and 11b that extend in the second direction intersecting the first direction. The reflector electrodes 20A and 20B include a plurality of reflector electrode fingers 21a and 21b that extend in the second direction. Among the plurality of comb electrode fingers 11a and 11b, the comb electrode finger closest to the reflector electrode 20A (or 20B) is defined as a first end-side electrode finger, and the comb electrode fingers arranged in a direction from the first end-side electrode finger toward the center of the IDT electrode 10 are sequentially defined as nth end-side electrode fingers (n is a natural number). Regarding the electrode fingers of the plurality of comb electrode fingers 11a and 11b and the plurality of reflector electrode fingers 21a and 21b, the center-to-center distance in the first direction between the electrode fingers adjacent to each other in the first direction is defined as a pitch, and a pitch between the nth end-side electrode finger and the (n+1)th end-side electrode finger is defined as an nth end-side pitch. Among the pitches arranged from the first end-side electrode finger to the comb electrode finger positioned in the center of the IDT electrode 10, the mth end-side pitch is smaller than an average pitch of pitches of the plurality of comb electrode fingers 11a and 11b except for the mth end-side pitch. In a region where the IDT electrode 10 is formed, when a region from the first end-side electrode finger to the mth end-side electrode finger is defined as the end region, the IDT electrode 10 includes the thinned electrode disposed in the end region.

Thus, the location of the thinned electrode in the end region of the IDT electrode 10 enables reduction of ripples close to the resonance band (resonant frequency) and adjustment of the fractional bandwidth (resonance bandwidth).

Furthermore, for example, in the acoustic wave device 1, a number of comb electrode fingers disposed between the reflector electrode 20A (or 20B) and the thinned electrode is greater than or equal to zero and smaller than or equal to three.

In this way, the longitudinal mode ripples can be further reduced or prevented.

Furthermore, for example, in the acoustic wave device 1, the IDT electrode 10 includes a plurality of the thinned electrodes disposed in the end region. The end region is bifurcated into the first end region close to the reflector electrode 20A (or 20B) and the second end region close to the center of the IDT electrode 10. The thinning rate is higher in the first end region than in the second end region.

In this way, the longitudinal mode ripples can be further reduced or prevented.

Furthermore, for example, in the acoustic wave device 1, the number of thinned electrodes disposed in the end region is greater than or equal to one and smaller than or equal to four.

In this way, the longitudinal mode ripples can be further reduced or prevented.

Furthermore, for example, in the acoustic wave device 1, the regions where the IDT electrode 10 is provided include two end regions positioned at both ends of the IDT electrode 10 in the first direction and the central region interposed between the two end regions. The IDT electrode 10 includes a plurality of thinned electrodes disposed in the end regions and at least one thinned electrode disposed in the central region. The thinning rate is higher in the end regions than in the central region.

Thus, the thinned electrodes are distributed more in the end regions than in the central region, and accordingly, ripples close to the resonance band (resonant frequency) can be further reduced or prevented and the fractional bandwidth (resonance bandwidth) can be adjusted.

Furthermore, for example, in the acoustic wave device 1, no thinned electrode is disposed in the central region.

Thus, the thinned electrodes are concentrated in the end regions, and accordingly, ripples close to the resonance band (resonant frequency) can be further reduced or prevented and the fractional bandwidth (resonance bandwidth) can be adjusted.

Furthermore, for example, in the acoustic wave device 1, the piezoelectric substrate 50 includes the piezoelectric layer 51 including the first main surface 51a and the second main surface 51b that are opposite from each other, the support substrate 54 disposed on the second main surface 51b side of the piezoelectric layer 51, the low acoustic velocity layer 52 which is disposed between the piezoelectric layer 51 and the support substrate 54 and in which the bulk wave acoustic velocity is lower than the bulk wave acoustic velocity in the piezoelectric layer 51 and the support substrate 54, and the high acoustic velocity layer 53 which is disposed between the low acoustic velocity layer 52 and the support substrate 54 and in which the bulk wave acoustic velocity is higher than the bulk wave acoustic velocity in the low acoustic velocity layer 52.

Thus, the Q-value can be significantly improved in the resonant frequency and the anti-resonant frequency. That is, because the acoustic wave device having a high Q-value can be provided, an acoustic wave filter with a small insertion loss can be provided with this acoustic wave device.

Furthermore, for example, in the acoustic wave device 1A according to a modification of an example embodiment of the present invention, the piezoelectric substrate is the monocrystal piezoelectric substrate 50A made of lithium niobate, and the acoustic wave device 1A further includes the insulator layer 60 disposed on the piezoelectric substrate 50A so as to allow the IDT electrode 10 to be embedded therein.

Thus, the acoustic wave device 1A having improved frequency-temperature characteristics can be provided.

Furthermore, according to an example embodiment of the present invention, the filter 200 includes the acoustic wave device 1.

Thus, a low-loss acoustic wave filter that can reduce or prevent ripples close to the pass band and allow the adjustment of the pass bandwidth can be provided.

Furthermore, according to an example embodiment of the present invention, the multiplexer 300 includes the common terminal 301, the filter 200 connected to the common terminal 301, and the filter 250 connected to the common terminal 301.

Thus, the pass bandwidth of the filter 200 can be adjusted, and the insertion loss in the pass band of the filter 250 can be reduced or prevented.

Although the acoustic wave devices, the acoustic wave filters, and the multiplexers have been described with reference to the example embodiments described above, the acoustic wave devices, the acoustic wave filters, and the multiplexers according to the present invention are not limited to the above-described example embodiments. The present invention also includes other example embodiments provided by combining any components of the above-described example embodiments, modifications obtained by making various changes to the above-described example embodiments which will occur to those skilled in the art without departing from the scope and gist of the present invention, and various apparatuses including the acoustic wave devices, the acoustic wave filters, and the multiplexers according to example embodiments of the present invention.

Example embodiments of the present invention can be widely used in communication devices such as, for example, cellular phones as a low-loss and high-attenuation acoustic wave filter and multiplexer applicable to multi-band frequency standards.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate;
an interdigital transducer electrode on the piezoelectric substrate; and
a reflector electrode on the piezoelectric substrate and adjacent to the interdigital transducer electrode in a first direction; wherein
the interdigital transducer electrode includes a plurality of comb electrode fingers extending in a second direction intersecting the first direction;
the reflector electrode includes a plurality of reflector electrode fingers extending in the second direction;
among the plurality of comb electrode fingers, a comb electrode finger closest to the reflector electrode is defined as a first end-side electrode finger, and the comb electrode fingers arranged in a direction from the first end-side electrode finger toward a center of the interdigital transducer electrode are sequentially defined as nth end-side electrode fingers, where n is a natural number;
among electrode fingers of the plurality of comb electrode fingers and the plurality of reflector electrode fingers, a center-to-center distance in the first direction between the electrode fingers adjacent to each other in the first direction is defined as a pitch, and a pitch between an nth end-side electrode finger and an (n+1)th end-side electrode finger is defined as an nth end-side pitch;
among pitches arranged from the first end-side electrode finger to a comb electrode finger located in the center of the interdigital transducer electrode, an mth end-side pitch is smaller than an average of pitches of the plurality of comb electrode fingers except for the mth end-side pitch; and
in a region where the interdigital transducer electrode is provided, when a region from the first end-side electrode finger to the mth end-side electrode finger is defined as an end region, the interdigital transducer electrode includes a thinned electrode in the end region.

2. The acoustic wave device according to claim 1, wherein a number of comb electrode fingers of the plurality of comb electrode fingers between the reflector electrode and the thinned electrode is greater than or equal to zero and smaller than or equal to three.

3. The acoustic wave device according to claim 1, wherein
the interdigital transducer electrode includes a plurality of the thinned electrodes in the end region;
the end region is bifurcated into a first end region in a vicinity of the reflector electrode and a second end region in a vicinity of the center of the interdigital transducer electrode; and
a thinning rate is higher in the first end region than in the second end region.

4. The acoustic wave device according to claim 1, wherein a number of thinned electrodes in the end region is greater than or equal to one and smaller than or equal to four.

5. The acoustic wave device according to claim 1, wherein
regions where the interdigital transducer electrode is located include two end regions at both ends of the interdigital transducer electrode in the first direction and a central region interposed between the two end regions;
the interdigital transducer electrode includes a plurality of the thinned electrodes in the end regions and at least one thinned electrode disposed in the central region; and
a thinning rate is higher in the end regions than in the central region.

6. The acoustic wave device according to claim 1, wherein
the interdigital transducer electrode includes two end regions at both ends of the interdigital transducer electrode in the first direction and a central region interposed between the two end regions; and
no thinned electrode is provided in the central region.

7. The acoustic wave device according to claim 1, wherein
the piezoelectric substrate includes:
a piezoelectric layer including a first main surface and a second main surface that are opposite from each other;
a support substrate on a second main surface side of the piezoelectric layer;
a low acoustic velocity layer between the piezoelectric layer and the support substrate, a bulk wave acoustic velocity being lower in the low acoustic velocity layer than in the piezoelectric layer and the support substrate; and
a high acoustic velocity layer between the low acoustic velocity layer and the support substrate, the bulk wave acoustic velocity being higher in the high acoustic velocity layer than in the low acoustic velocity layer.

8. The acoustic wave device according to claim 1, wherein
the piezoelectric substrate is a monocrystal piezoelectric substrate including lithium niobate; and
the acoustic wave device further includes an insulator layer on the piezoelectric substrate such that the interdigital transducer electrode is embedded therein.

9. An acoustic wave filter comprising:
the acoustic wave device according to claim 1.

10. The acoustic wave filter according to claim 9, wherein a number of comb electrode fingers of the plurality of comb electrode fingers between the reflector electrode and the thinned electrode is greater than or equal to zero and smaller than or equal to three.

11. The acoustic wave filter according to claim 9, wherein
the interdigital transducer electrode includes a plurality of the thinned electrodes in the end region;
the end region is bifurcated into a first end region in a vicinity of the reflector electrode and a second end region in a vicinity of the center of the interdigital transducer electrode; and
a thinning rate is higher in the first end region than in the second end region.

12. The acoustic wave filter according to claim 9, wherein a number of thinned electrodes in the end region is greater than or equal to one and smaller than or equal to four.

13. The acoustic wave filter according to claim 9, wherein
regions where the interdigital transducer electrode is provided include two end regions at both ends of the interdigital transducer electrode in the first direction and a central region interposed between the two end regions;
the interdigital transducer electrode includes a plurality of the thinned electrodes in the end regions and at least one thinned electrode disposed in the central region; and
a thinning rate is higher in the end regions than in the central region.

14. The acoustic wave filter according to claim 9, wherein
the interdigital transducer electrode includes two end regions at both ends of the interdigital transducer electrode in the first direction and a central region interposed between the two end regions; and
no thinned electrode is provided in the central region.

15. The acoustic wave filter according to claim 9, wherein
the piezoelectric substrate includes:
a piezoelectric layer including a first main surface and a second main surface that are opposite from each other;
a support substrate on a second main surface side of the piezoelectric layer;
a low acoustic velocity layer between the piezoelectric layer and the support substrate, a bulk wave acoustic velocity being lower in the low acoustic velocity layer than in the piezoelectric layer and the support substrate; and
a high acoustic velocity layer between the low acoustic velocity layer and the support substrate, the bulk wave acoustic velocity being higher in the high acoustic velocity layer than in the low acoustic velocity layer.

16. The acoustic wave filter according to claim 9, wherein
the piezoelectric substrate is a monocrystal piezoelectric substrate including lithium niobate; and
the acoustic wave device further includes an insulator layer on the piezoelectric substrate such that the interdigital transducer electrode is embedded therein.

17. A multiplexer comprising:
a common terminal;
the acoustic wave filter according to claim 9, the acoustic wave filter being connected to the common terminal; and
a first filter connected to the common terminal.

18. The multiplexer according to claim 17, wherein a number of comb electrode fingers of the plurality of comb electrode fingers between the reflector electrode and the thinned electrode is greater than or equal to zero and smaller than or equal to three.

19. The multiplexer according to claim 17, wherein
the interdigital transducer electrode includes a plurality of the thinned electrodes in the end region;
the end region is bifurcated into a first end region in a vicinity of the reflector electrode and a second end region in a vicinity of the center of the interdigital transducer electrode; and
a thinning rate is higher in the first end region than in the second end region.

20. The multiplexer according to claim 17, wherein a number of thinned electrodes in the end region is greater than or equal to one and smaller than or equal to four.
